(19) United States
(12) Patent Application Publication
(10) Pub. No.: US 2025/0333312 A1
(43) Pub. Date: Oct. 30, 2025

(54) METHOD FOR TREATING CARBON-BASED STRUCTURE, METHOD FOR TREATING GRAPHENE STRUCTURE, AND PELLICLE FOR PHOTO MASK INCLUDING PELLICLE MEMBRANE

(71) Applicant: Samsung Electronics Co., Ltd., Suwon-si (KR)

(72) Inventors: Mun Ja Kim, Suwon-si (KR); Jing Xian Wu, Daejeon (KR); Hae Shin Lee, Daejeon (KR); Yun Han Lee, Suwon-si (KR)

(73) Assignee: Korea Advanced Institute of Science and Technology, Daejeon (KR)

(21) Appl. No.: 19/093,763

(22) Filed: Mar. 28, 2025

(30) Foreign Application Priority Data
Apr. 25, 2024 (KR) 10-2024-0055487

(51) Int. Cl. C01B 32/194; G03F 1/64

(52) U.S. Cl. CPC C01B 32/194; G03F 1/64; C01B 2204/04; C01P 2002/01; C01P 2002/02; C01P 2002/82; C01P 2002/84

(57) ABSTRACT

A method for treating a carbon-based structure is provided. The method for treating the carbon-based structure includes treating a defect area of the carbon-based structure with a polyphenol compound to form a polyphenol compound structure, obtaining an image of the defect area with the polyphenol compound structure, and performing a thermal-treatment on the polyphenol compound structure.

### CROSS-REFERENCE TO RELATED APPLICATION

This application claims priority from Korean Patent Application No. 10-2024-0055487, filed Apr. 25, 2024, in the Korean Intellectual Property Office, and all the benefits accruing therefrom under 35 U.S.C. 119, the contents of which in its entirety are herein incorporated by reference.

### BACKGROUND

### Field

The present disclosure relates to a method for treating a carbon-based structure, a method for treating a graphene structure, and a pellicle for a photomask including a pellicle membrane.

### Description of Related Art

A pellicle for a photomask may be provided in a form of a film on a photomask to protect the photomask from external contamination materials during an optical lithography process. The pellicle for the photomask may have high transmittance of light used in the lithography process and may satisfy various properties such as heat dissipation characteristics, strength, uniformity, durability, and stability. A decreased line width of a semiconductor device/an electronic circuit may be used. In order to achieve the reduced line width, a wavelength of the light used in the lithography process may become shorter, and a pellicle material suitable for the light source used in the lithography process may be developed.

Two-dimensional graphene made of carbon has excellent mechanical, electrical, and/or thermal properties and may be applied to various fields. Graphene may be produced by mechanical exfoliation, epitaxial growth using a silicon carbide substrate, or CVD (Chemical Vapor Deposition) using catalytic metals.

When graphene is produced by the chemical vapor deposition, defect areas such as grain boundaries and/or pinholes may be generated. The above defect areas may affect the performance of the material containing the graphene.

### SUMMARY

In some embodiments of the present disclosure, a method for treating a carbon-based structure that may detect a defect in the carbon-based structure and may improve performance of a material containing the carbon-based structure may be provided.

In some embodiments of the present disclosure, a method for treating a graphene structure that may detect a defect in the graphene structure and may improve performance of a material containing the graphene structure may be provided.

In some embodiments of the present disclosure, a pellicle for a photo mask that may detect a defect in a pellicle membrane and improve performance of the pellicle membrane may be provided.

Purposes according to the present disclosure are not limited thereto. Other purposes and advantages according to the present disclosure that are not mentioned may be understood based on the following descriptions, and may be more clearly understood based on embodiments according to the present disclosure. Further, it will be easily understood that the purposes and advantages according to the present disclosure may be realized using means shown in the claims or combinations thereof.

A method for treating a carbon-based structure according to some embodiments of the present disclosure includes treating a defect area of the carbon-based structure with a polyphenol compound to form a polyphenol compound structure; obtaining an image of the defect area with the polyphenol compound structure; and performing a thermal-treatment on the polyphenol compound structure.

A method for treating a graphene structure according to some embodiments of the present disclosure includes providing a graphene structure, wherein the graphene structure includes a support and a graphene layer on the support; treating a defect area of the graphene structure with a polyphenol compound to form a polyphenol compound structure; obtaining an image of the defect area; detecting a defect of the graphene structure based on the image; and performing a thermal-treatment on the polyphenol compound structure to form a carbon-based material layer different from the graphene layer on the defect area.

A pellicle for a photo mask according to some embodiments of the present disclosure includes a pellicle membrane, wherein the pellicle membrane includes: a graphene layer; and a carbon-based material layer on the graphene layer that is different from the graphene layer, wherein a thickness of the carbon-based material layer is different from a thickness of the graphene layer.

Specific details of other embodiments are included in the detailed description and drawings.

### BRIEF DESCRIPTION OF DRAWINGS

The above and other aspects and features of the present disclosure will become more apparent by describing in detail some embodiments thereof with reference to the attached drawings, in which:

FIG. 1 is a flowchart for schematically illustrating a method for treating a carbon-based structure according to some embodiments of the present disclosure;

FIG. 2 and FIG. 3 are diagrams illustrating intermediate steps of a method for treating a carbon-based structure according to some embodiments of the present disclosure;

FIG. 4 is a diagram illustrating an electroplating process in the method for treating the carbon-based structure according to some embodiments of the present disclosure;

FIG. 5 is an image detected with an optical microscope of a defect area of a carbon-based structure according to some embodiments of the present disclosure;

FIG. 6 is an image detected with a fluorescence microscope of a defect area of a carbon-based structure according to some embodiments of the present disclosure;

FIG. 7 is a graph of an intensity of a Raman spectrum of a polyphenol compound structure immediately after the polyphenol compound has been deposited according to some embodiments of the present disclosure;

FIG. 8 is a graph of an intensity of a Raman spectrum of a polyphenol compound structure after the polyphenol compound has been deposited and then a predetermined time has elapsed according to some embodiments of the present disclosure;

FIG. 9 is a diagram of an intermediate step for illustrating a method for treating a carbon-based structure according to some embodiments of the present disclosure, and illustrates an area corresponding to an area S in FIG. 3;

FIG. 10 is an image obtained using a transmission electron microscope (TEM) of a polyphenol compound structure after a thermal-treatment of the polyphenol compound structure according to some embodiments of the present disclosure;

FIGS. 11 to 13 are diagrams illustrating carbon-based structures treated according to some embodiments of the present disclosure; and

FIG. 14 is a schematic diagram illustrating an apparatus for treating a carbon-based structure according to some embodiments of the present disclosure.

### DETAILED DESCRIPTIONS

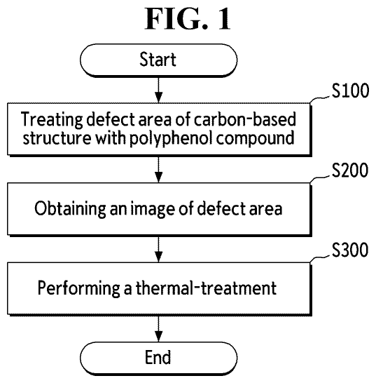

FIG. 1 is a flowchart for schematically illustrating a method for treating a carbon-based structure according to some embodiments of the present disclosure.

Referring to FIG. 1, the method for treating the carbon-based structure according to some embodiments may include a step S100 of treating a defect area of the carbon-based structure with a polyphenol compound to form a polyphenol compound structure, a step S200 obtaining an image of the defect area with the polyphenol compound structure, e.g., to measure a defect, and a step S300 of performing a thermal-treatment on the polyphenol compound structure, e.g., to repair the defect. In some embodiments, the carbon-based structure comprises graphene.

Hereinafter, a method for treating a carbon-based structure according to some embodiments will be described in detail.

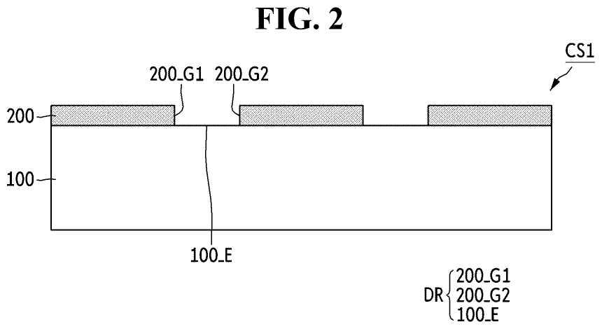

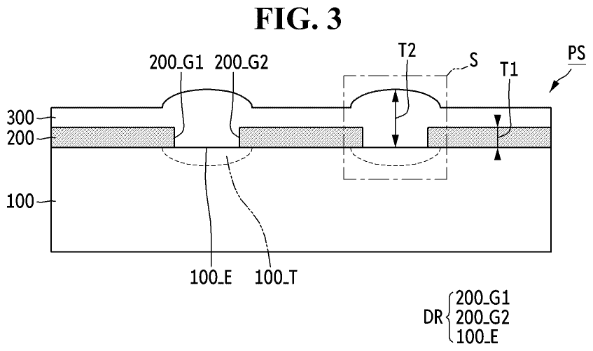

FIG. 2 and FIG. 3 are intermediate diagrams for illustrating a method for treating a carbon-based structure according to some embodiments of the present disclosure.

Referring to FIG. 2, a first carbon-based structure CS1 according to some embodiments may include a support 100 and a first carbon-based material layer 200 on support 100.

The support 100 may include an oxidizable material. The support 100 may include, but is not limited to, a conductive material such as copper (Cu).

For example, the first carbon-based material layer 200 may include at least one of graphene, graphite, carbon nanotubes, carbon nanosheets, nanoribbons, and diamond. However, embodiments of the present disclosure are not limited thereto.

In some embodiments, graphene may include a substance in which a plurality of carbon atoms are covalently coupled to each other to form a two-dimensional film, and which typically has a sp2 bond. The carbon atoms that make up graphene constitute a 6-membered ring as a basic repeating unit. However, the graphene may further include a 5-membered ring and/or a 7-membered ring based on a grain boundary formed in a graphene layer. Furthermore, the graphene may have a defect in a form of a vacancy in which an atom-level binding structure is empty or broken. The graphene may be composed of a single layer or may be composed of multiple layers by stacking the single layers.

In some embodiments, when the first carbon-based structure CS1 includes graphene, the first carbon-based structure CS1 may be referred to as a graphene structure. When the first carbon-based material layer 200 may include graphene, the first carbon-based material layer 200 may be a graphene layer.

The first carbon-based structure CS1 may include a defect area DR. The defect area DR may include edge areas 200_G1 and 200_G2 of the first carbon-based material layer 200, and an exposed area 100_E of the support 100.

FIG. 3 is a diagram for illustrating the step S100 of treating the polyphenol-based material.

Referring to FIG. 3, a polyphenol compound structure PS may be formed by treating the defect area DR of the first carbon-based structure (CS1 in FIG. 2) with a polyphenol compound.

The edge areas 200_G1a and 200G2 may include grain boundaries of the first carbon-based material layer 200. The edge areas 200_G1 and 200G2 of the first carbon-based material layer 200 may be areas where dangling bonds via which the first carbon-based material layer binds to the polyphenol compound are produced.

Within the support 100, a modified area 100_T in which the support binds to the polyphenol compound may be produced. The modified area 100_T may be an area where the support 100, which may include the conductive material such as copper, is oxidized as it reacts with the polyphenol compound. In this case, for example, the modified area 100_T may include copper oxide (CuOx).

In some embodiments of the present disclosure, the polyphenol compound is a type of an aromatic alcohol compound and may include a plurality of hydroxy groups.

For example, the polyphenol compound may include at least one of tannic acid, dopamine, flavonoid, ellagitannin, chitosan-catechol, hyaluronic acid-gallol, hyaluronic acid-catechol, and fluorescein isothiocyanate (FITC). However, the technical idea of the present disclosure is not limited thereto.

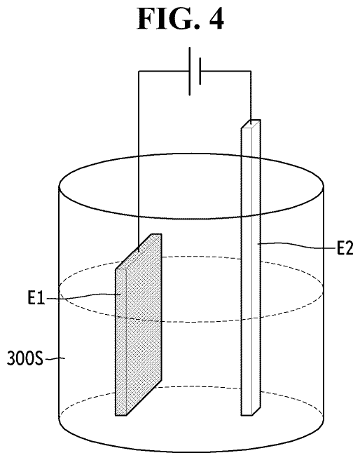

FIG. 4 is a diagram illustrating an electroplating process in the method for treating the carbon-based structure according to some embodiments of the present disclosure.

For example, referring to FIGS. 3 and 4, a polyphenol compound layer 300 of FIG. 3 may be selectively deposited on the defect area DR using electroplating as shown in FIG. 4. In this case, the first carbon-based structure CS1 having the support 100, which may be a copper substrate, and the first carbon-based material layer 200 (e.g., a graphene layer) deposited thereon is connected to a first electrode (anode) E1. A platinum (Pt) electrode may be used as the second electrode (cathode) E2. A polyphenol compound solution 300S may be used as electrolyte.

For example, the first carbon-based structure CS1 may be treated with dopamine using electroplating, such that the polyphenol compound layer 300 may be formed in the defect area DR of the first carbon-based structure CS1. In this case, the electroplating may be performed for 4 hours at 1V in solution of a dopamine concentration of 1 mg/mL, 10 mM PBS phosphate buffer, and a pH 5.5.

As the electroplating progresses, the polyphenol compound layer 300 may be formed via oxidation and polymerization reactions of the polyphenol compound.

On the first electrode E1, the polyphenol compound may lose electrons and become oxidized. The oxidized polyphenol compound may constitute a polyphenol compound polymer.

Referring again to FIG. 3, the polyphenol compound polymer may be coated on the defect area DR as described above. Due to the charge accumulation occurring in the edge areas 200_G1 and 200_G2 of the first carbon-based material layer 200 and the exposed area 100_E of the support 100, the second carbon-based material layer (polyphenol compound layer) 300 may be selectively deposited on the edge areas 200_G1 and 200_G2 of the first carbon-based material layer 200 and the exposed area 100_E of the support 100.

Specifically, in the edge areas 200_G1 and 200G2 of the first carbon-based material layer 200, the first carbon-based material layer 200 may bind to the polyphenol compound via the dangling bonds. The modified area 100_T reacts with the polyphenol compound, such that the polyphenol compound may coordinate with the conductive material in the exposed area 100_E of the support 100. After the thermal-treatment on the polyphenol compound as described later has been performed, the modified area 100_T may be converted into a carbide layer.

Accordingly, the polyphenol compound structure PS may be formed. The polyphenol compound layer 300 may cover the defect area (DR in FIG. 2). Additionally, the polyphenol compound layer 300 may be also formed on an area of the first carbon-based material layer 200 other than the defect area (DR in FIG. 2) thereof.

A thickness T2 of the polyphenol compound layer 300 from an upper surface of the support 100 may be larger than a thickness T1 of the first carbon-based material layer 200 from the upper surface of the support 100. For example, the thickness T2 of the polyphenol compound layer 300 may be larger than a thickness of one layer of graphene. However, embodiments of the present disclosure are not limited thereto.

This polyphenol compound structure PS may be formed using a process other than an electroplating process. For example, the first carbon-based structure CS1 may be immersed in the polyphenol compound solution 300S, such that the polyphenol compound layer 300 may selectively bind to the defect area DR.

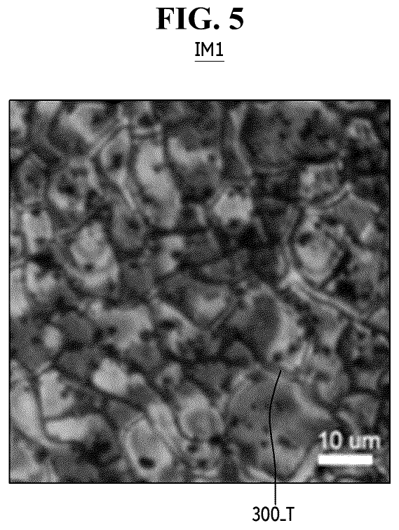

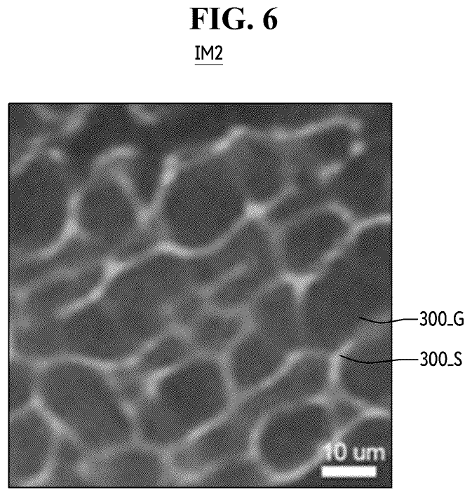

FIG. 5 is an image detected with an optical microscope of a defect area of a carbon-based structure according to some embodiments of the present disclosure. FIG. 6 is an image detected with a fluorescence microscope of a defect area of a carbon-based structure according to some embodiments of the present disclosure.

FIG. 5 and FIG. 6 are images illustrating the step S200 of obtaining an image of the defect area DR.

Referring to FIG. 5, an optical microscope (not shown) may acquire a first image IM1 of an area 300_T where the polyphenol compound is formed on the modified area (100_T in FIG. 3).

Referring to FIG. 6, a second image IM2 on the defect area DR may be obtained with the polyphenol compound structure PS. The second image IM2 may be acquired by the fluorescence microscope (not shown).

The polyphenol compound, such as fluorescein isothiocyanate (FITC) may be excited by an excitation beam to generate fluorescence light.

The fluorescence microscope (not shown) may detect fluorescence light generated from the excited polyphenol compound and may generate the second image IM2 on the defect area DR binding to the second carbon-based material layer (e.g., polyphenol compound layer) 300 based on the fluorescence light.

A relatively dark portion in the second image IM2 may include an area 300_G where the polyphenol compound layer 300 is formed on the edge areas 200_G1 and 200_G2 of the first carbon-based material layer 200. A relatively bright portion in the second image IM2 may include an area 300_S where the polyphenol compound layer 300 is formed on the exposed area of the support 100.

When using the fluorescence microscope (not shown), the defect area of the carbon-based structure may be effectively visualized over a larger area of a mm scale than when using the optical microscope (not shown).

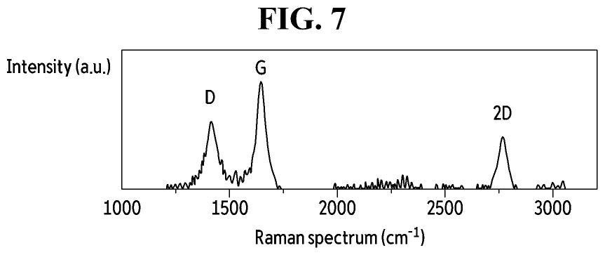

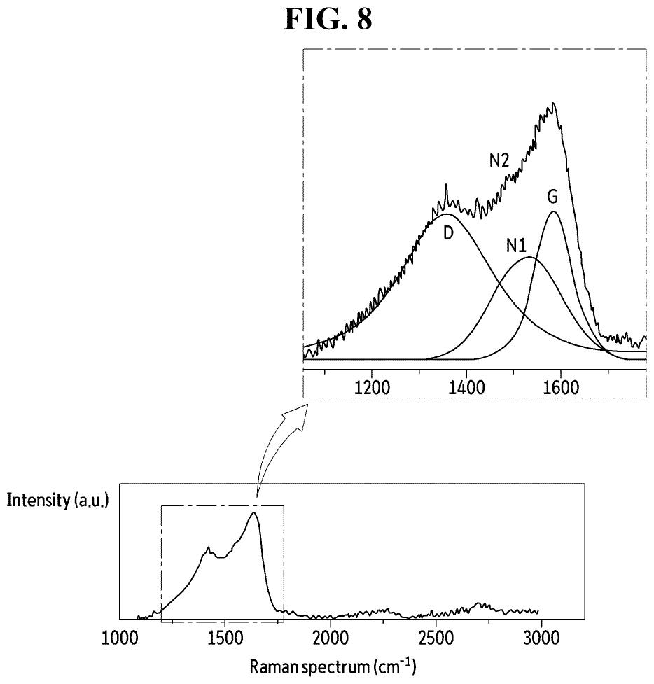

FIG. 7 is a graph of the intensity of a Raman spectrum of the polyphenol compound structure immediately after the polyphenol compound has been deposited according to some embodiments of the present disclosure. FIG. 8 is a graph of the intensity of a Raman spectrum of the polyphenol compound structure after the polyphenol compound has been deposited and then, a predetermined time has elapsed according to some embodiments of the present disclosure.

A 2D peak in the Raman spectrum may be used to measure a thickness of graphene. Generally, the 2D peak of graphene may be found around 2700 cm⁻¹.

A G peak in the Raman spectrum may represent a peak commonly found in graphite-based materials. The G peak may result from a mode in which adjacent carbon atoms vibrate in opposite directions. Generally, the G peak of graphene may be found around 1584 cm⁻¹.

In the Raman spectrum, a D peak may represent a peak caused by a defect within a crystal. The D peak may be observed near the edge of graphene or when there are many defects in graphene. It may be determined that as an intensity of the D peak is greater, the number of defects in the graphene is larger. Generally, the D peak of graphene may be found around 1356 cm⁻¹.

The intensity of the D peak in the Raman spectrum may be a relative value. Therefore, a defect amount of graphene may be based on a ratio of the intensity of the D peak to the intensity of the G peak.

The treatment of the polyphenol compound according to some embodiments of the present disclosure may be identified based on the Raman spectrum.

As shown in FIG. 7 and FIG. 8, after the treatment of the polyphenol compound, a new N1 peak (1530 cm⁻¹) (FIG. 8) corresponding to the vibration mode of the polyphenol compound is expressed in addition to the D peak of 1356 cm⁻¹ and the G peak of 1584 cm⁻¹ derived from the graphene. As the polyphenol compound is formed on the carbon-based structure, a N2 peak may be expressed by the D peak at 1356 cm⁻¹, the G peak at 1584 cm⁻¹, and the N1 peak at 1530 cm⁻¹.

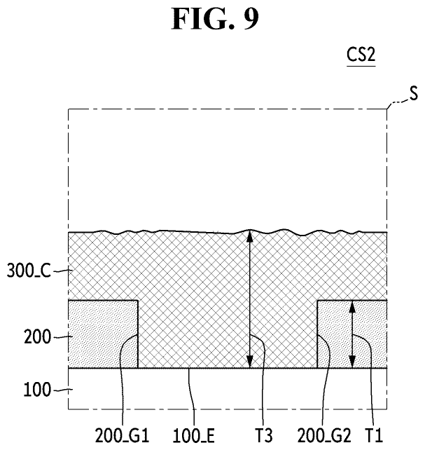

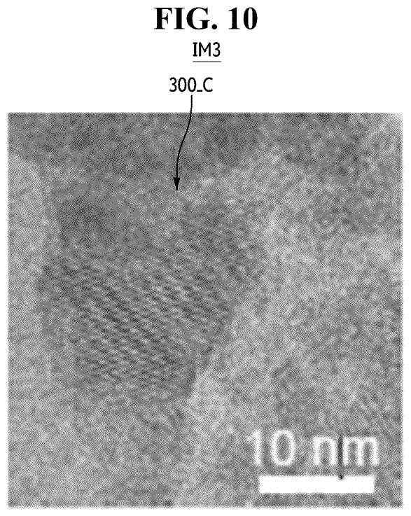

FIG. 9 is a diagram of an intermediate step for illustrating a method for treating a carbon-based structure according to some embodiments of the present disclosure, and illustrates an area corresponding to an area S in FIG. 3. FIG. 10 is an image obtained using a transmission electron microscope (TEM) of a polyphenol compound structure after the thermal-treatment of the polyphenol compound structure according to some embodiments of the present disclosure.

FIG. 9 and FIG. 10 illustrate the step S300 of repairing the defect in graphene.

Referring to FIG. 9 and FIG. 10, the thermal-treatment may be performed on the polyphenol compound structure (PS in FIG. 3) to form a second carbon-based material layer 300_C on the defect area (DR in FIG. 2). The second carbon-based material layer 300_C may cover the defect area (DR in FIG. 2). Additionally, the second carbon-based material layer 300_C may be formed on an area of the first carbon-based material layer 200 other than the defect area (DR in FIG. 2) thereof.

For example, a thermal-treatment process may be performed in a hydrogen and/or argon atmosphere at a temperature range of about 900° C. to 1000° C. In this case, a hydrogen content may be about 3% and an argon content may be about 97%. However, embodiments of the present disclosure are not limited thereto.

The second carbon-based material layer 300_C may be different from the first carbon-based material layer 200. A thickness T3 of the second carbon-based material layer 300_C may be different from the thickness T1 of the first carbon-based material layer 200. For example, the thickness T3 of the second carbon-based material layer 300_C may be larger than the thickness T1 of the first carbon-based material layer 200.

For example, the thickness T3 of the second carbon-based material layer 300_C may be non-uniform. However, embodiments of the present disclosure are not limited thereto. A shape of the second carbon-based material layer 300_C is not limited to that shown in the drawing.

The second carbon-based material layer 300_C may include a different material from that of the first carbon-based material layer 200. For example, a grain orientation of the second carbon-based material layer 300_C may be different from a grain orientation of the first carbon-based material layer 200. However, embodiments of the present disclosure are not limited thereto. For example, a grain size of the second carbon-based material layer 300_C may be different from a grain size of the first carbon-based material layer 200. However, embodiments of the present disclosure are not limited thereto.

The second carbon-based material layer 300_C produced after the thermal-treatment of the polyphenol compound structure PS may include, for example, amorphous carbon and/or nanocrystalline carbon. As an amount of the polyphenol compound deposited for defect detection increases, an amount of amorphous carbon present within the second carbon-based material layer 300_C may increase.

However, when the amount of the deposited polyphenol compound is reduced or minimized and the thermal-treatment is performed under a high vacuum condition, a content of the amorphous carbon present within the second carbon-based material layer 300_C may be reduced.

Absence or presence of the amorphous carbon may be identified based on the D peak of the Raman spectrum shown in FIG. 7. When the D peak exists, it may be determined that the amorphous carbon exists. Furthermore, the amount thereof may be quantified based on the ratio of the intensity of the D peak to the intensity of the G peak.

The second carbon-based material layer 300_C may include only nanocrystalline carbon after a considerable period of time has elapsed after the thermal-treatment.

The second carbon-based material layer 300_C may be formed such that the second carbon-based structure CS2 having improved mechanical, electrical, and/or thermal properties compared to those of a carbon-based structure obtained when the first carbon-based material layer 200 is used alone may be obtained.

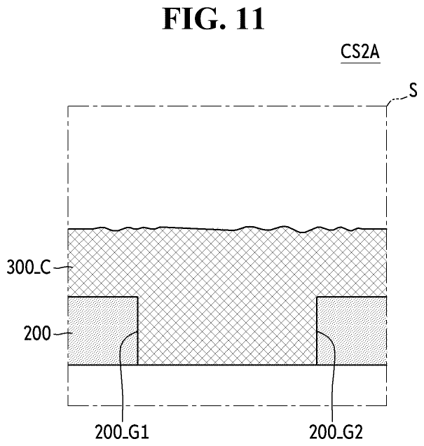

FIGS. 11 to 13 are diagrams illustrating carbon-based structures treated according to some embodiments of the present disclosure. For convenience, the following description focuses on differences thereof from the descriptions set forth above using FIGS. 1 to 10.

Referring to FIG. 11, a 2A-th carbon-based structure CS2A may not include the support (100 in FIG. 9). In this case, for example, after the polyphenol compound structure PS has been formed, the support (100 in FIG. 9) may be removed. However, the technical idea of the present disclosure is not limited thereto.

For example, the 2A-th carbon-based structure CS2A may be included in a pellicle membrane for the photo mask.

In this case, the pellicle membrane may include the first carbon-based material layer as a graphene layer 200, and the carbon-based material layer 300_C is on the graphene layer 200. The carbon-based material layer 300_C is different than the graphene layer 200. A thickness of the carbon-based material layer 300_C may be different from a thickness of the graphene layer 200. An orientation of the grain of the carbon-based material layer 300_C may be different from an orientation of the grain of the graphene layer 200. The grain size of the carbon-based material layer 300_C may be different from the grain size of the graphene layer 200. The carbon-based material layer 300_C may include nanocrystalline carbon.

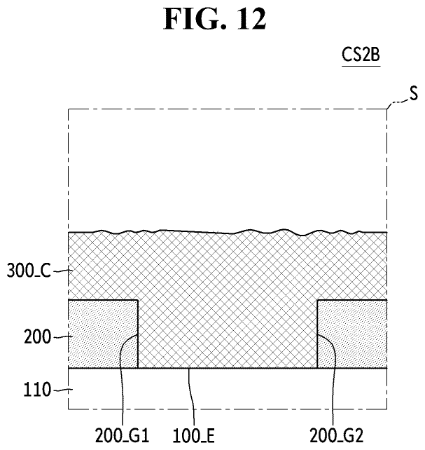

Referring to FIG. 12, the support 110 of a 2B-th carbon-based structure CS2B may include a material other than copper (Cu).

For example, the support 110 may include at least one of silicon (Si), mica, and quartz. The support 110 may include bulk silicon or SOI (silicon-on-insulator). The support 110 may be a silicon substrate, or may include a material other than silicon, such as silicon germanium, indium antimonide, lead telluride compound, indium arsenide, indium phosphide, gallium arsenide or gallium antimonide. Alternatively, the support 110 may have a base substrate and an epitaxial layer formed on the base substrate. However, the technical idea of the present disclosure is not limited thereto.

In another example, the support 110 may be at least one of an etch stop film, an adhesive layer, a CTE (Coefficient of Thermal Expansion) control material, a stress relief material, a conductive barrier material, and a hydrogen resistant material. For example, when the support 110 is an etch stop film, the support may include at least one of SiN or SiCN. When the support 110 is an adhesive layer, the support may include a non-conductive material. When the support 110 is a conductive barrier material, the support may include at least one of Ti, Ta, TiN, and TaN. However, this is an example, and the technical idea of the present disclosure is not limited thereto.

Accordingly, the mechanical, electrical, and/or thermal properties of each of the etch stop film, the adhesive layer, the CTE control material, the stress relief material, the conductive barrier material, the hydrogen resistance material, etc. may be further improved.

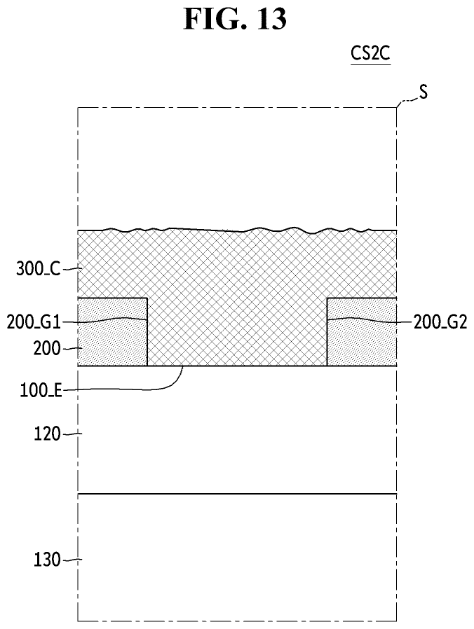

Referring to FIG. 13, a support of a 2C-th carbon-based structure CS2C may have a structure in which a second support 120 including a conductive material is stacked on a first support 130 including silicon (Si). For example, the conductive material may include copper (Cu). However, embodiments of the present disclosure are not limited thereto.

Although not specifically shown, each of the carbon-based structures CS2, CS2A, CS2B, and CS2C may be on at least one of the etch stop film, the adhesive layer, the CTE control material, the stress relief material, the conductive barrier material, the hydrogen resistance material, etc. Accordingly, the mechanical, electrical, and/or thermal properties of each of the etch stop film, the adhesive layer, the CTE control material, the stress relief material, the conductive barrier material, the hydrogen resistance material, etc., may be further improved.

Furthermore, application of each of the carbon-based structures CS2, CS2A, CS2B, and CS2C is not limited to a semiconductor device. For example, each of the carbon-based structures CS2, CS2A, CS2B, and CS2C may be applied to home appliances and/or secondary batteries in which a graphene-based material may be utilized.

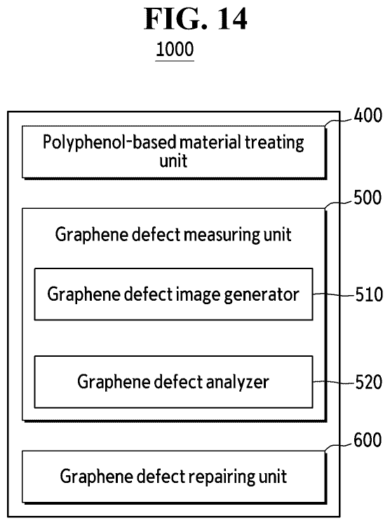

FIG. 14 is a schematic diagram illustrating an apparatus for treating a carbon-based structure according to some embodiments of the present disclosure. For convenience, the following description focuses on differences thereof from the descriptions as set forth above using FIGS. 1 to 10.

Referring to FIG. 14, an apparatus 1000 for treating a carbon-based structure according to some embodiments may include a polyphenol-based material treating unit 400, a graphene defect measuring unit 500, and a graphene defect repairing unit 600.

The polyphenol-based material treating unit 400 may treat the first carbon-based structure CS1 including the defect area DR with the polyphenol compound to form the polyphenol compound structure PS.

Referring to FIG. 4 and FIG. 14 together, the polyphenol-based material treating unit 400 may include an electroplating device including the first electrode E1 to which the first carbon-based structure CS1 is connected, the second electrode E2 as the platinum (Pt) electrode, and the polyphenol compound solution 300S as the electrolyte.

The graphene defect measuring unit 500 may generate the image (IM2 in FIG. 6) of the defect area (DR in FIG. 2) using the polyphenol compound structure (PS in FIG. 3). The graphene defect measuring unit 500 may include a graphene defect image generator 510 and a graphene defect analyzer 520.

The graphene defect image generator 510 may include a light source (not shown) that generates and emits an excitation beam, and the fluorescence microscope (not shown) that detects the fluorescence light generated from the excited polyphenol compound, and generates the image (IM2 in FIG. 6) in which a position of the polyphenol compound is indicated, based on the fluorescence light.

The graphene defect measuring unit 500 may include, for example, a personal computer (PC). However, embodiments of the present disclosure are not limited thereto.

The graphene defect analyzer 520 may analyze information about the defect using the image (IM2 in FIG. 6).

The graphene defect repairing unit 600 may perform a thermal-treatment on the polyphenol compound structure (PS in FIG. 3). The graphene defect repairing unit 600 may form a carbon-based layer, that is, the second carbon-based structure (CS2 in FIG. 9) different from the first carbon-based structure (CS1 in FIG. 9) on the defect area.

Each of the components (for example, the polyphenol-based material treating unit 400, the graphene defect measuring unit 500, and the graphene defect repairing unit 600) of the apparatus 1000 for treating the carbon-based structure, and sub-components thereof may be implemented entirely in a hardware manner, or implemented in a combination of hardware and software. For example, each of the components (for example, the polyphenol-based material treating unit 400, the graphene defect measuring unit 500, and the graphene defect repairing unit 600) of the apparatus 1000 for treating the carbon-based structure, and sub-components thereof may include both an element for performing an intended function, and software for operating the element and processing data obtained by the element. Furthermore, each of the components (for example, the polyphenol-based material treating unit 400, the graphene defect measuring unit 500, and the graphene defect repairing unit 600) of the apparatus 1000 for treating the carbon-based structure, and sub-components thereof may not be necessarily limited to one physical device, but may be embodied as an assembly or a collection of a plurality of parts used together to achieve the intended function.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or characteristics of the present disclosure. Therefore, it should be appreciated that the embodiments as described above is not restrictive but illustrative in all respects.

What is claimed is:

1. A method for treating a carbon-based structure, the method comprising:
treating a defect area of the carbon-based structure with a polyphenol compound to form a polyphenol compound structure;
obtaining an image of the defect area with the polyphenol compound structure; and
performing a thermal-treatment on the polyphenol compound structure.

2. The method of claim 1, wherein the carbon-based structure includes a support and a first carbon-based material layer on the support,
wherein the defect area includes an edge area of the first carbon-based material layer and an exposed area of the support.

3. The method of claim 2, wherein the polyphenol compound binds to each of the edge area of the first carbon-based material layer and the exposed area of the support.

4. The method of claim 2, wherein the support includes a conductive material.

5. The method of claim 2, wherein the first carbon-based material layer includes at least one of graphene, graphite, carbon nanotubes, and nanoribbon.

6. The method of claim 1, wherein the step of treating the defect area of the carbon-based structure with the polyphenol compound to form the polyphenol compound structure comprises selectively depositing the polyphenol compound on the defect area using electroplating.

7. The method of claim 1, wherein the polyphenol compound includes fluorescein isothiocyanate (FITC).

8. The method of claim 1, wherein the step of obtaining the image of the defect area includes:
detecting fluorescence light generated from the polyphenol compound; and
generating the image of the defect area binding to the polyphenol compound, based on the fluorescence light.

9. The method of claim 1, wherein the step of performing the thermal-treatment on the polyphenol compound structure includes forming a second carbon-based material layer on the defect area.

10. The method of claim 9, wherein the second carbon-based material layer includes amorphous carbon.

11. The method of claim 9, wherein a grain orientation of the second carbon-based material layer is different from a grain orientation of the carbon-based structure.

12. A method for treating a graphene structure, the method comprising:
providing the graphene structure, wherein the graphene structure includes a support and a graphene layer on the support;
treating a defect area of the graphene structure with a polyphenol compound to form a polyphenol compound structure;
obtaining an image of the defect area;
detecting a defect of the graphene structure based on the image; and
performing a thermal-treatment on the polyphenol compound structure to form a carbon-based material layer different from the graphene layer on the defect area.

13. The method of claim 12, wherein the image of the defect area includes:
a first area where the polyphenol compound is formed on an edge area of the graphene layer; and
a second area where the polyphenol compound is formed on an exposed portion of the support.

14. The method of claim 13, wherein the step of obtaining the image of the defect area includes generating an image of the graphene structure in the first and second areas using a fluorescence microscope.

15. The method of claim 12, wherein a thickness of the carbon-based material layer is different from a thickness of the graphene layer.

16. The method of claim 12, wherein the support includes copper (Cu).

17. The method of claim 12, wherein the support includes silicon (Si).

18. A pellicle for a photo mask, wherein the pellicle includes a pellicle membrane,
and the pellicle membrane includes:
a graphene layer; and
a carbon-based material layer on the graphene layer that is different from the graphene layer,
wherein a thickness of the carbon-based material layer is different from a thickness of the graphene layer.

19. The pellicle for the photo mask of claim 18, wherein a grain orientation of the carbon-based material layer is different from a grain orientation of the graphene layer.

20. The pellicle for the photo mask of claim 19, wherein the carbon-based material layer includes nanocrystalline carbon.
